(19) United States
(12) Patent Application Publication
(10) Pub. No.: US 2012/0212252 A1
(43) Pub. Date: Aug. 23, 2012

(54) Printed Circuit Board Registration Testing

(76) Inventors: Scott H. Aronson, Grafton, MA (US); Gerald G. Gagnon, Nashua, NH (US)

(21) Appl. No.: 13/029,187

(22) Filed: Feb. 17, 2011

(51) Int. Cl. G01R 31/28; H05K 3/20; H01F 5/00

(52) U.S. Cl. 324/763.01; 336/200; 29/852

(57) ABSTRACT

A structure for determining misregistration of layers of a printed circuit board. A first conductive pattern is on a first layer of the printed circuit board. A second conductive pattern on a second layer of the printed circuit board. There is a hole through the first layer and the second layer of the printed circuit board. There is electrically conductive material in the hole. If the first layer and the second layer of the printed circuit board are registered properly, the first conductive pattern and the second conductive pattern are not electrically continuous with the conductive material in the hole. If either or both of the first layer and the second layer are a misregistered layer, the conductive trace on the misregistered layer is electrically continuous with the conductive material in the hole.

### BACKGROUND

This specification describes a structure for detecting misregistration of layers of a printed circuit board, particularly a circuit board embodying a planar magnetic structure.

### SUMMARY

In one aspect of the specification, a structure for determining misregistration of layers of a printed circuit board includes a first conductive pattern on a first layer of the printed circuit board; a second conductive pattern on a second layer of the printed circuit board; a hole through the first layer and the second layer of the printed circuit board; and electrically conductive material in the hole. If the first layer and the second layer of the printed circuit board are registered properly, the first conductive pattern and the second conductive pattern are not electrically continuous with the conductive material in the hole. If either or both of the first layer and the second layer are a misregistered layer, the conductive trace on the misregistered layer is electrically continuous with the conductive material in the hole. The structure may further include an opening in the first conductive pattern and the second conductive pattern. The hole may be positioned in the opening if the first layer and the second layer are registered properly. The opening may be substantially disc shaped and the diameter of the opening may be greater than the diameter of the hole by 0.2 mm or less. The first conductive pattern and the second conductive pattern may form coils of an electrical device. The electrical device may be an inductor. The electrical device may be a transformer. The structure may further include a third conductive pattern on a third layer of the printed circuit board. The hole may be through the third layer of the printed circuit board. If the third layer of the printed circuit board is registered properly, the third conductive pattern may not be electrically continuous with the conductive material in the hole. If the third layer is misregistered, the conductive trace on the misregistered layer may be electrically continuous with the conductive material in the hole. If the either or both of the first layer and the second layer are a misregistered layer misregistered by an amount sufficient to cause a short circuit between the first conductive pattern and the second conductive pattern, the conductive trace on the misregistered layer may be electrically continuous with the conductive layer in the hole.

In another aspect of the specification, an electrical device, includes a portion of a conductive coil on each of a plurality of layers of a printed circuit board; a conductive feature on a common position on each of the plurality of layers of a printed circuit board; and a conductive through hole through the layers of the printed circuit board. The conductive through hole is electrically continuous with the conductive feature of a layer of the printed circuit board that is misregistered. The conductive through hole is not electrically continuous with the conductive feature of a layer of the printed circuit board that is not misregistered. The electrical device may be a transformer. The electrical device may be an inductor. The conductive feature may defines a non-conductive opening and the conductive through hole may be positioned in the non-conductive opening if the corresponding layer is not misregistered.

In another aspect of the specification, a method includes placing a first conductive pattern on a first layer of a printed circuit board and placing a second conductive pattern on a second layer of the printed circuit board. The first conductive pattern and the second conductive pattern have a common feature. The method further includes forming a plated hole in the printed circuit board. The plated hole is positioned so that if either or both of the first layer and the second layer are misregistered, the plating in the plated hole is electrically continuous with the feature on the misregistered layer. If neither of the first layer and the second layer are misregistered, the plated hole is not electrically continuous with the feature on either layer. The feature may include an opening and the hole may be positioned in the opening. The first conductive pattern and the second conductive pattern may form a portion of a coil of an electrical device. The electrical device may be an inductor. The electrical device may be a transformer. The common feature may includes a conductive pattern that surrounds a substantially circular non-conductive opening. The method may further include dimensioning the diameter of the opening and the diameter of the plated hole to control the sensitivity of a misregistration test. The method may further include determining the electrical continuity of the plated hole and the conductive pattern on the first layer and the electrical continuity of the plated hole and the conductive pattern on the second layer to determine misregistration of the first layer and the second layer.

Other features, objects, and advantages will become apparent from the following detailed description, when read in connection with the following drawing, in which:

BRIEF DESCRIPTION OF THE SEVERAL VIEWS OF THE DRAWING

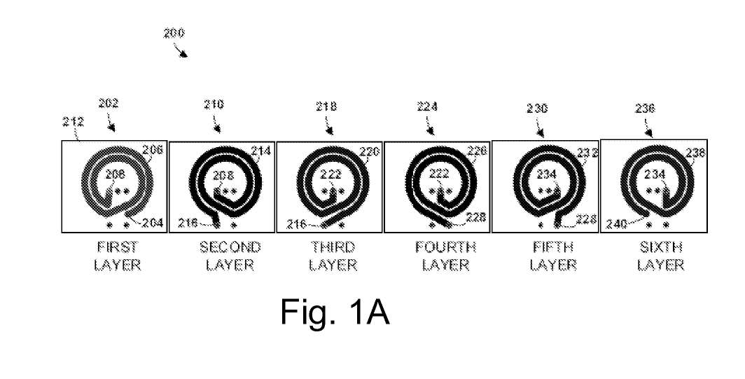

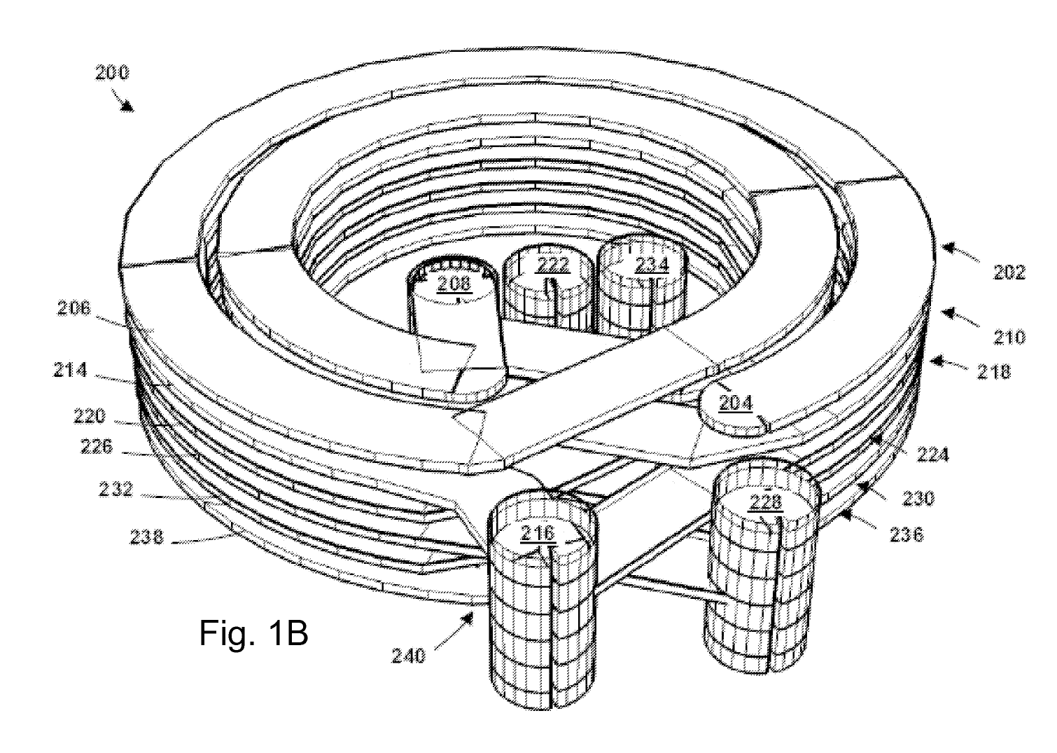

FIG. 1A is a top plan view of six layers of a planar inductor;

FIG. 1B is a perspective view of a planar inductor;

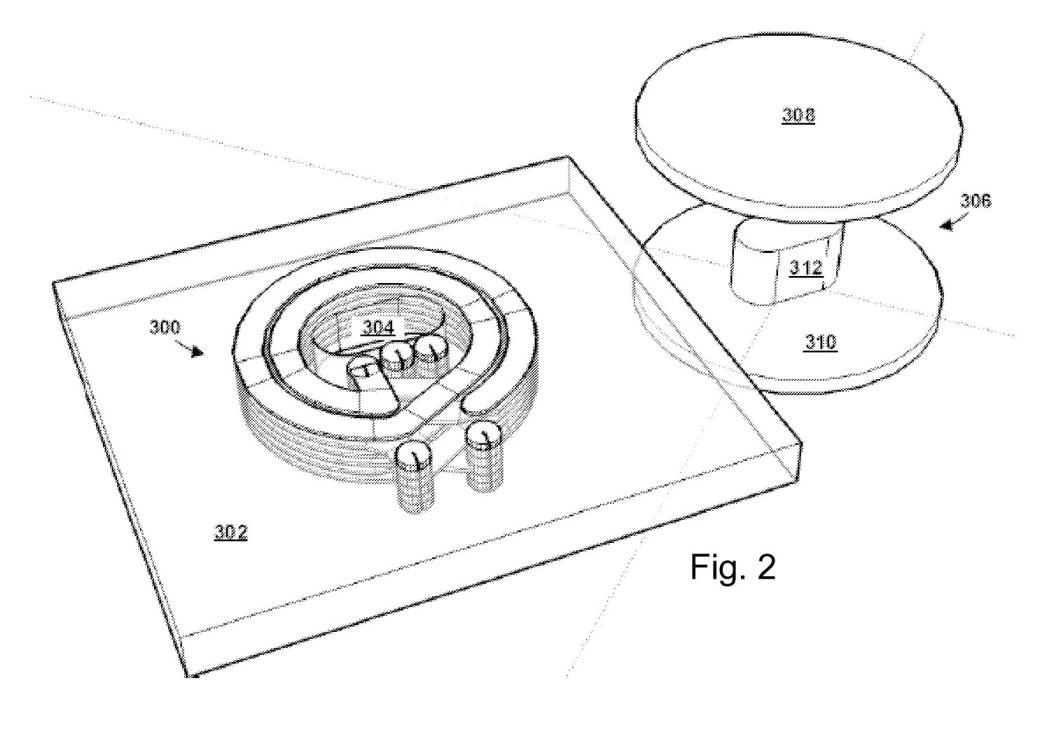

FIG. 2 is a perspective view of a planar inductor with an aperture and of a ferrite core;

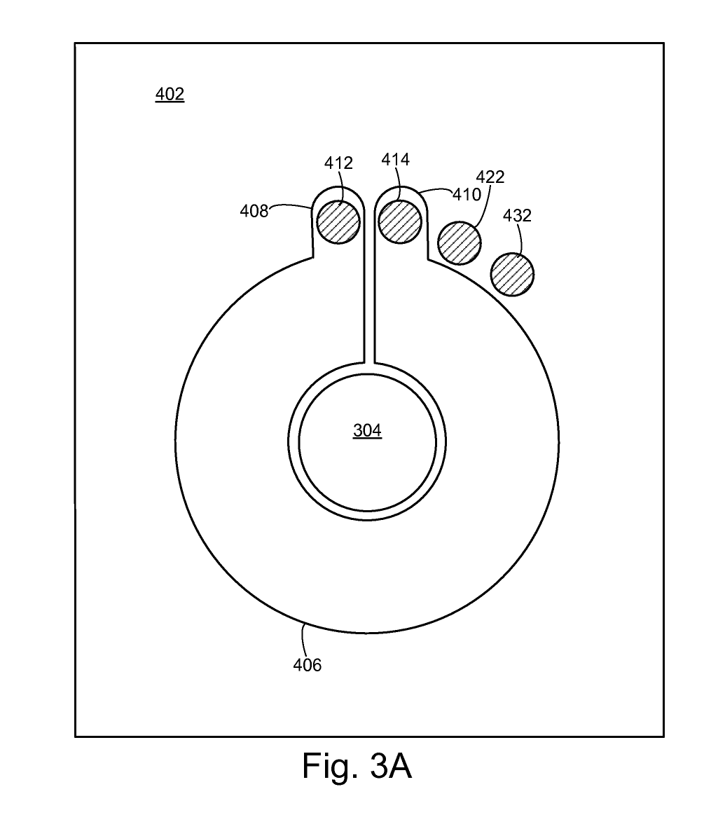

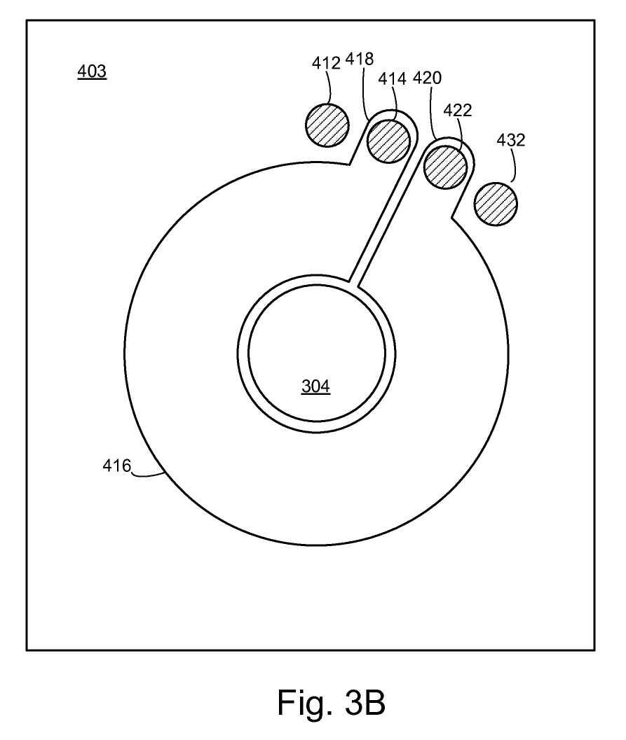

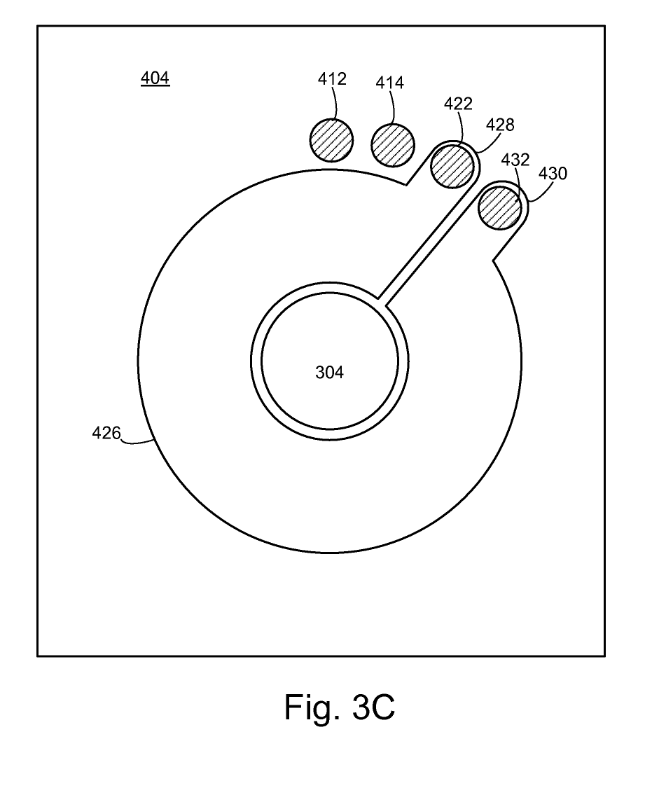

FIGS. 3A-3C are simplified plan views of layers of a printed circuit board embodying a planar inductor;

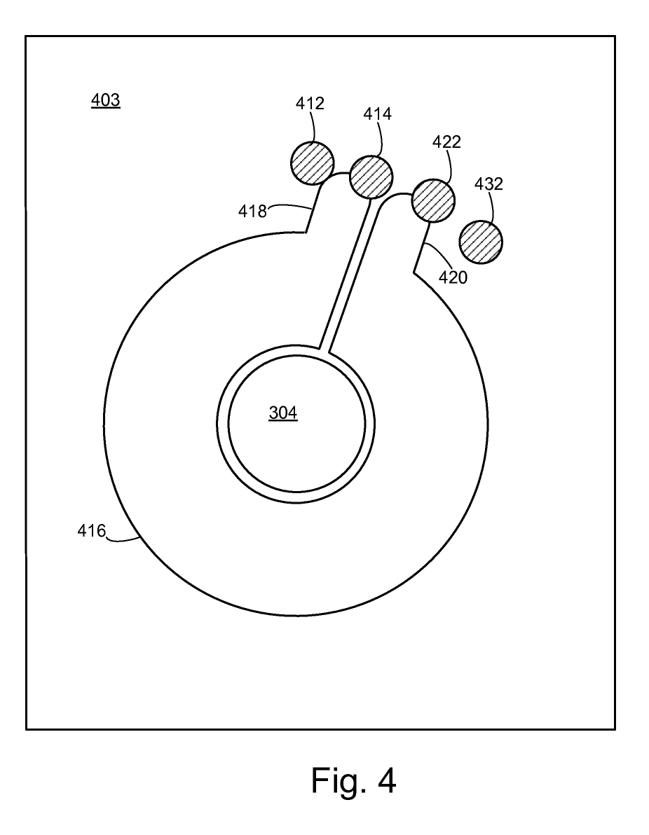

FIG. 4 is a simplified plan view of a layer of a printed circuit board embodying a planar inductor, illustrating misregistration;

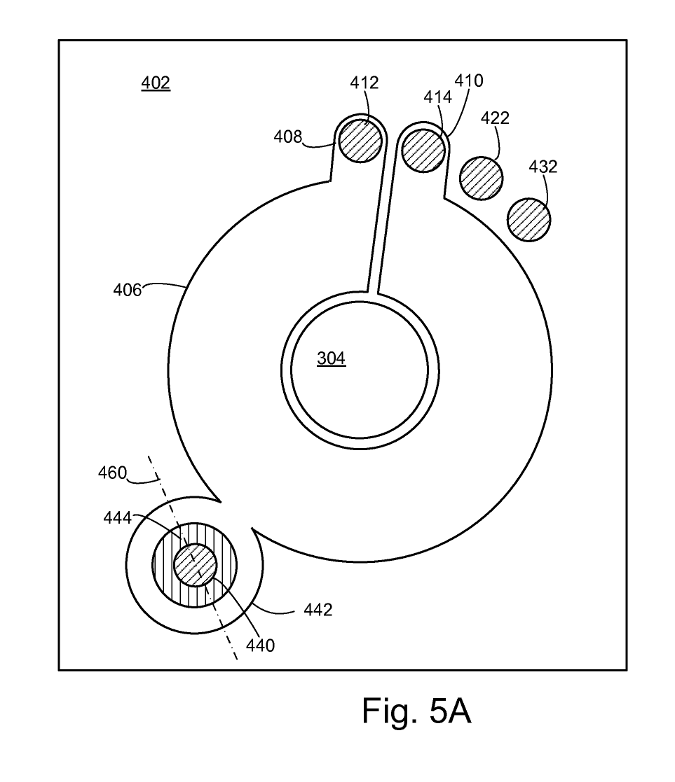

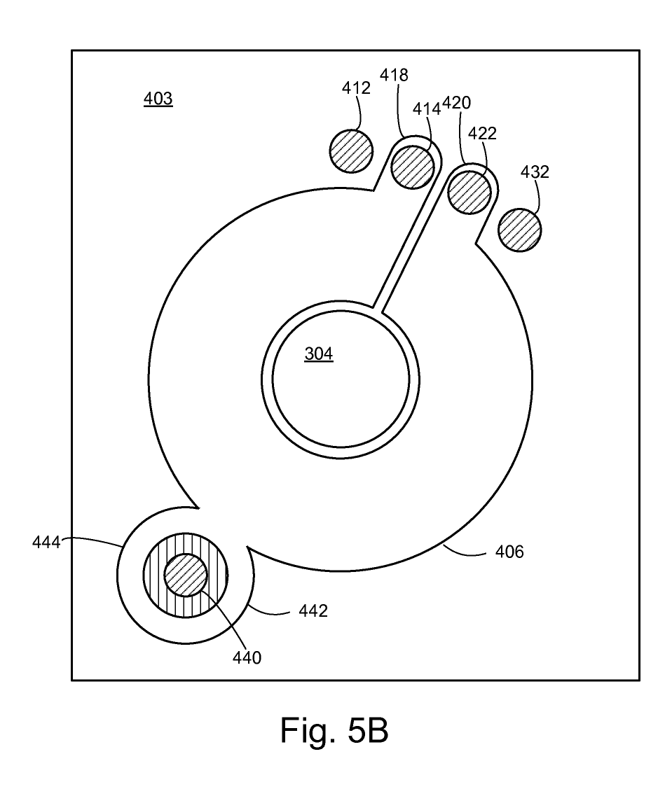

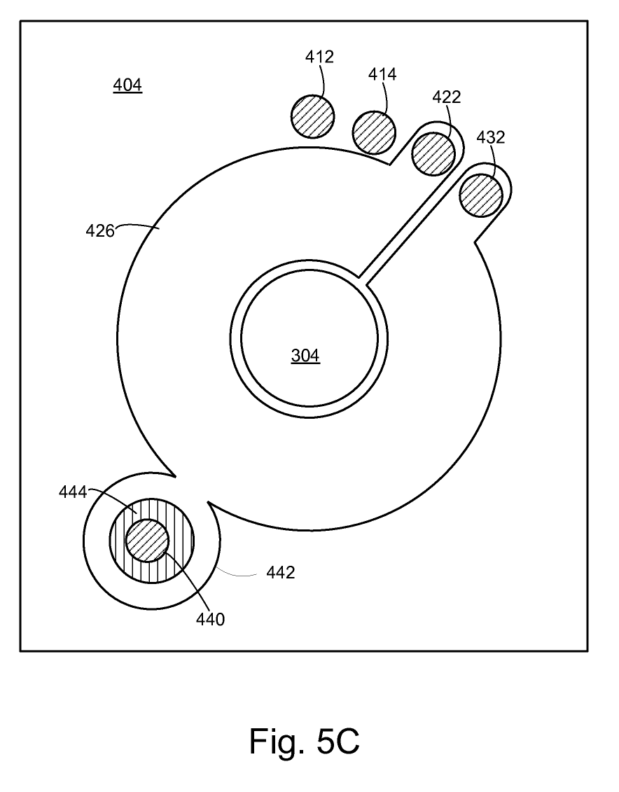

FIG. 5A-5C are simplified plan views of layers of a printed circuit board embodying a planar inductor and a structure of detecting misregistration;

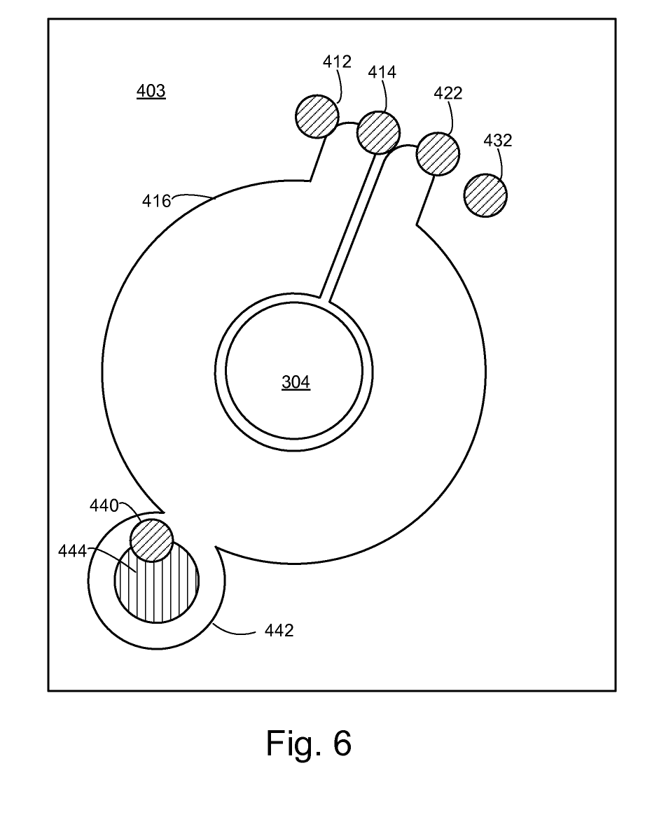

FIG. 6 is a simplified plan view of a layer of a printed circuit board illustrating the operation of the structure for detecting misregistration;

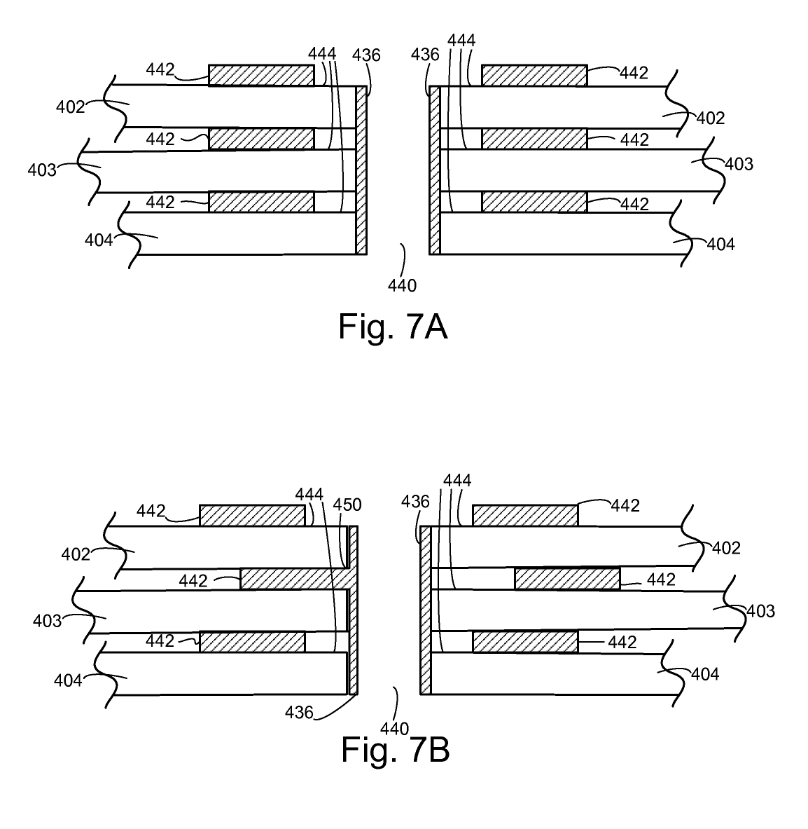

FIGS. 7A and 7B are diagrammatic cross sections of the structure for detecting misregistration; and

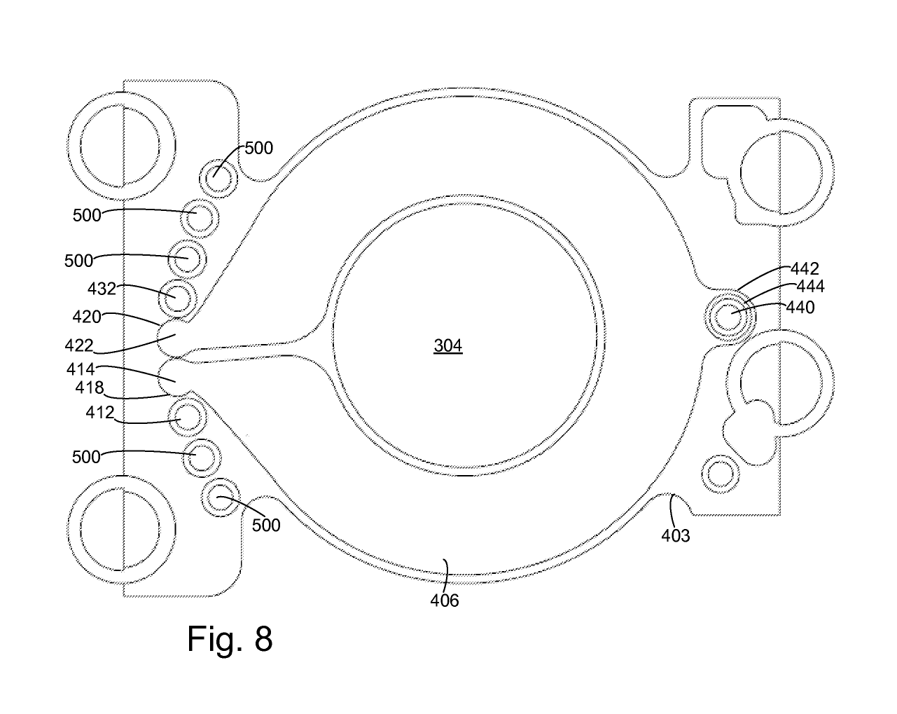

FIG. 8 is a plan view of one layer of a an actual implementation of a printed circuit board embodying a structure of detecting misregistration.

### DETAILED DESCRIPTION

This specification describes a procedure for testing misregistration of layers of printed circuit boards (PCBs), particularly misregistration that can cause short circuits. The test is particularly useful in certain situations. Examples of the situations are: (1) if there are features on some of all of the layers that that are sufficiently similar in geometry and placement that corresponding features on one level can be placed in a common position on the PCB, and it is possible to add a feature that it is in a common position on each PCB level so that, when the levels are aligned as intended, the feature on one level lies directly above the feature on the level above and/or the level below, if any; (2) if the PCB is not populated by components that facilitate simple testing of short circuits; (3) if several similar devices are fabricated on the same circuit board (and possibly later separated); (4) it is necessary to test for short circuits in a circuit that is has low resistance; and others.

One type of PCB device that has similar features in similar positions on successive layers, that is fabricated on PCBs without large numbers of components that facilitate simple testing of short circuits, and that is typically fabricated on the same circuit board is a device that has similar traces at similar positions on several layers of a PCB, for example, planar magnetic devices such as planar transformers and planar inductors. FIGS. 1A and 1B show a planar inductor fabricated on as described in U.S. Pat. 7,432,793, incorporated herein by reference in its entirety. FIG. 1A illustrates an inductor 200 fabricated on a multiple layer printed circuit board (PCB). The multiple layer printed circuit board includes six layers. The layers actually lay on top of each other, but are shown next to each other for illustrative purposes. A first layer 202 can include a first terminal 204, a spiral winding 206 and a first via 208. The term “via” as used herein denotes a metalized through hole that couples one layer of a printed circuit to another layer. The first via 208 is used to interconnect the first layer 202 with a second layer 210. Using known techniques not described in detail herein, the spiral winding 206 can be formed either by chemically etching a layer of electrically conducting material, such as copper, deposited on the face of a circuit board 212, or by depositing electrically conducting material on the face of the circuit board 212. The spiral winding 206 can be circular, helical, rectangular, or any other suitable shape.

The second layer 210 can include the first via 208, a spiral winding 214, and a second via 216. The second via 216 is used to interconnect the second layer 210 with a third layer 218. The third layer 218 can include the second via 216, a spiral winding 220, and a third via 222. The third via 222 is used to interconnect the third layer 218 with a fourth layer 224. The fourth layer 224 can include the third via 222, a spiral winding 226, and a fourth via 228. The fourth via 228 is used to interconnect the fourth layer 224 with a fifth layer 230. The fifth layer 230 can include the fourth via 228, a spiral winding 232, and a fifth via 234. The fifth via 234 is used to interconnect the fifth layer 230 with a sixth layer 236. The sixth layer 236 can include the fifth via 234, a spiral winding 238, and a second terminal 240.

FIG. 1B is a perspective view of the inductor 200 of FIG. 1A. The first terminal 204 of the first layer 202 is shown adjacent to the fourth via 228. In practice, the first terminal 204 can be formed in any desired location. The second terminal 240 of the sixth layer 236 is located behind the second via 216. In practice, the second terminal 240 can be formed in any desired location.

FIG. 2 illustrates a perspective view of an inductor 300 fabricated on a multiple layer printed circuit board 302 including an aperture 304 and a ferrite core 306 in a disassembled state. The ferrite core 306 can include a top section 308 and a bottom section 310. The top section 308 and the bottom section 310 are assembled together such that a portion 312 of the bottom section 310 is positioned inside the aperture 304. The core is typically assembled after the PCB fabrication.

As is most easily seen in FIG. 1B and FIG. 2, the spiral windings are sufficiently similar from layer to layer that corresponding features on one level can be placed in a common position, and it is possible to add a feature to the spiral winding so that it is in a common position on each PCB level and so that, when the levels are aligned as intended, the feature on one level lies directly above the feature on the level above and/or the level below, if any. Additionally, the windings are electrically continuous. These features will be further discussed below.

FIGS. 3A-3C show a simplified view of a portion of three layers 402 , 403, and 404, respectively, of a printed circuit board on which a planar inductor (for example as shown in unsimplified form in FIGS. 1A-2) is fabricated. In FIG. 3A, printed circuit board layer 402 includes a trace 406 which forms one coil of a planar inductor. The trace has two ends 408 and 410. One of the ends 408 and the plating of a through hole 412 are electrically continuous. For clarity, in this and all subsequent views, the plated through holes or vias will be shown with diagonal hatching. End 410 is electrically continuous with plated through hole 414. Unlike the implementation of FIGS. 1A-2, in this implementation, there is one coil of the winding on each layer of the PCB. The planar inductor is the only component on the printed circuit board.

In FIG. 3B, layer 403 has a trace 416 with ends 418 and 420. End 418 is electrically continuous with the plating in through hole 414. End 420 is electrically continuous with through hole 422.

In FIG. 3C, layer 404 has a trace 426 with ends 428 and 430. End 428 is electrically continuous with the plating in through hole 422 and end 430 is electrically continuous with through hole 432. In an actual implementation, there may be more than three layers, and correspondingly more through holes 412, 414, 422, 432.

The holes that form the vias are drilled after the printed circuit boards are fabricated. If one of the layers is not aligned properly with the other layers (known as “misregistration”), the through holes that are plated through to form the vias may not be properly positioned with the metal traces that form the windings and problems may result. One of the problems may be short circuiting, illustrated in FIG. 4.

FIG. 4 is a view of a portion of layer 403, demonstrating short circuiting caused by misregistration. If layer 403 is misregistered, trace 416 on layer 403 may not be aligned properly with the plated through holes 412, 414, 422, and 432. In the example of FIG. 4, layer 403 is misregistered. Trace 416 of layer 403 is misaligned with the through holes so that the plating in though hole 412 is short circuited to the plating in through hole 414 by end 418 of trace 416. The short circuit affects the inductance of the planar inductor.

Problems of the type shown in FIG. 4 are very difficult to detect. The defect may not be detectable visually, because the defect may be in an interior layer of the printed circuit board. The inductance cannot be measured directly during the printed circuit board fabrication process, because measuring the inductance directly requires a ferrite core 306 of FIG. 2 to be in place, which is not practical during the printed circuit board fabrication process. Simple, high speed tests such as continuity tests are not useful, because all portions of the planar inductor are electrically continuous.

FIG. 5A-5C shows a structure for detecting misregistration of printed circuit board layers. The structure is enabled because it is possible to add a feature to the spiral winding so that it is in a common position on each PCB level and so that, when the levels are aligned as intended, the feature on one level lies directly above the feature on the level above and/or the level below. A feature 442 is formed in traces 406, 416, and 426 are formed and, after the PCB is assembled, a hole is drilled through the feature and plated to form a plated through hole. The geometry and the dimensions of the through hole and the feature are such that (a) if the layers of the PCB are registered properly the test plated through hole 440 is not electrically coupled to any traces on any level of the PCB; but (b) if a layer of the PCB is misregistered enough to short circuit two windings, the misregistration is sufficient that the test plated through hole 440 becomes electrically continuous with feature 442 on the misregistered level.

In this example, the feature 442 includes an outward extension of the trace, with a circular opening 444 in the trace (that is a portion of the printed circuit board layer that is not covered by conductive material; for clarity, the opening is shown with vertical hatching) that is slightly larger than the diameter of the test plating through hole 440. Stated differently, the feature 442 surrounds and defines a substantially circular opening in the trace. The opening is positioned so that, with proper registration, the test through hole is within the opening, and the feature is not in electrical contact with plating in the plated through hole 440. FIGS. 5A-5C show, respectively, layers 402, 403, and 404, with layers 402 and 404 properly registered. Line 460 of FIG. 5A will be explained below.

FIG. 6 shows layer 403, with the feature 442 and the test plated through hole, with layer 402 misregistered, as in FIG. 4. Test plated through hole is now electrically continuous with feature 442. It can be seen that if the misregistration of layer 403 is in any direction by an amount sufficient to cause a short circuit, the test plated through hole 440 would be electrically continuous with the trace.

FIGS. 7A and 7B shows a diagrammatic cross section of the feature and the opening. The cross sections are in a plane perpendicular to the planes of FIGS. 3A-6, and intersecting with the planes of FIGS. 3A-6 along line 460 of FIG. 5A. The reference numbers correspond to like numbers in previous figures, and for purposes of illustration, conductive elements are shown with diagonal hatching. Element 436 indicates the plating in the plated through hole 440. FIG. 7A shows layers 402, 403, and 404 in proper registration. FIG. 7B shows layer 403 misregistered relative to layers 402 and 404. In FIG. 7B, the through hole plating 436 and the feature 442 are electrically coupled at 450.

Adjusting the sensitivity of the structure of FIGS. 5A-5C is easily done by varying the diameter of the opening 444 and the diameter of the test plated through hole 440. If the diameter of the opening is only slightly larger than the diameter of the plated test through hole, the test is very sensitive. If the diameter of the opening is significantly larger than the diameter of the test plated through hole, the test is less sensitive. In one example, the diameter of the opening is 1.4 mm and the diameter of the diameter of the hole is 1.1 mm, so the difference between the diameter of the opening and the diameter of the hole is 0.3 mm.

Electrical continuity (indicating failure) and lack of continuity between the test plated through hole and the any of the traces is easily tested with simple electrical tests.

FIG. 8 shows a layout of an actual implementation of the structure shown diagrammatically in FIG. 5B. The implementation of FIG. 8 has nine through holes. Four of the through holes 41, 414 (obscured by end 418 of trace 406), 422 (obscured by end 320 of trace 306), and 432 correspond to like numbered through holes in FIG. 5B. Through holes 500 are present in the actual implementation but are not shown in the diagrammatic view of FIG. 5B. Other reference numbers in FIG. 8 correspond to like numbered elements in FIG. 5B. Features not identified in FIG. 8 are not germane to the matter described in this specification.

Numerous uses of and departures from the specific apparatus and techniques disclosed herein may be made without departing from the inventive concepts. Consequently, the invention is to be construed as embracing each and every novel feature and novel combination of features disclosed herein and limited only by the spirit and scope of the appended claims.

What is claimed is:

1. A structure for determining misregistration of layers of a printed circuit board, comprising:
a first conductive pattern on a first layer of the printed circuit board;
a second conductive pattern on a second layer of the printed circuit board;
a hole through the first layer and the second layer of the printed circuit board; and
electrically conductive material in the hole, wherein
if the first layer and the second layer of the printed circuit board are registered properly, the first conductive pattern and the second conductive pattern are not electrically continuous with the conductive material in the hole; and
if either or both of the first layer and the second layer are a misregistered layer, the conductive trace on the misregistered layer is electrically continuous with the conductive material in the hole.

2. The structure of claim 1, further comprising an opening in the first conductive pattern and the second conductive pattern, wherein the hole is positioned in the opening if the first layer and the second layer are registered properly.

3. The structure of claim 2, wherein the opening is substantially disc shaped and wherein the diameter of the opening is greater than the diameter of the hole by 0.2 mm or less.

4. The structure of claim 1, wherein the first conductive pattern and the second conductive pattern form coils of an electrical device.

5. The structure of claim 4, wherein the electrical device is an inductor.

6. The structure of claim 4, wherein the electrical device is a transformer.

7. The structure of claim 1, further comprising:
a third conductive pattern on a third layer of the printed circuit board, wherein the hole is through the third layer of the printed circuit board, wherein
if the third layer of the printed circuit board is registered properly, the third conductive pattern is not electrically continuous with the conductive material in the hole; and
if the third layer is misregistered, the conductive trace on the misregistered layer is electrically continuous with the conductive material in the hole.

8. The structure of claim 1, wherein if the either or both of the first layer and the second layer are a misregistered layer misregistered by an amount sufficient to cause a short circuit between the first conductive pattern and the second conductive pattern, the conductive trace on the misregistered layer is electrically continuous with the conductive layer in the hole.

9. An electrical device, comprising:
a portion of a conductive coil on each of a plurality of layers of a printed circuit board;
a conductive feature on a common position on each of the plurality of layers of a printed circuit board;
a conductive through hole through the layers of the printed circuit board, wherein the conductive through hole is electrically continuous with the conductive feature of a layer of the printed circuit board that is misregistered; and
wherein the conductive through hole is not electrically continuous with the conductive feature of a layer of the printed circuit board that is not misregistered.

10. The electrical device of claim 9, wherein the electrical device is a transformer.

11. The electrical device of claim 9, wherein the electrical device is an inductor.

12. The electrical device of claim 9, wherein the conductive feature defines a non-conductive opening, and wherein the conductive through hole is positioned in the non-conductive opening if the corresponding layer is not misregistered.

13. A method comprising:
placing a first conductive pattern on a first layer of a printed circuit board;
placing a second conductive pattern on a second layer of the printed circuit board, the first conductive pattern and the second conductive pattern having a common feature;
forming a plated hole in the printed circuit board, wherein the plated hole is positioned
so that if either or both of the first layer and the second layer is misregistered, the plating in the plated hole is electrically continuous with the feature on the misregistered layer; and
so that if neither of the first layer and the second layer are misregistered, the plated hole is not electrically continuous with the feature on either layer.

14. The method of claim 13, wherein the feature comprises an opening and wherein the hole is positioned in the opening.

15. The method of claim 13, wherein the first conductive pattern and the second conductive pattern form a portion of a coil of an electrical device.

16. The method of claim 15, wherein the electrical device is an inductor.

17. The method of claim 15, wherein the electrical device is a transformer.

18. The method of claim 13, wherein the common feature comprises a conductive pattern that surrounds a substantially circular non-conductive opening.

19. The method of claim 18. further comprising dimensioning the diameter of the opening and the diameter of the plated hole to control the sensitivity of a misregistration test.

20. The method of claim 13, further comprising determining the electrical continuity of the plated hole and the conductive pattern on the first layer and the electrical continuity of the plated hole and the conductive pattern on the second layer to determine misregistration of the first layer and the second layer.
